(19) United States
(12) Patent Application Publication
(10) Pub. No.: US 2026/0150196 A1
(43) Pub. Date: May 28, 2026

(54) LAMINATED SUBSTRATE AND METHOD FOR MANUFACTURING THE SAME

(71) Applicant: Monolithic Power Systems, Inc., Kirkland, WA (US)

(72) Inventors: Yingjiang Pu, Chengdu (CN); Hunt Hang Jiang, Saratoga, CA (US)

(21) Appl. No.: 19/402,200

(22) Filed: Nov. 26, 2025

(30) Foreign Application Priority Data
Nov. 28, 2024 (CN) 202411721864. 2

(51) Int. Cl. H05K 1/11; H05K 1/02; H05K 3/00; H05K 3/40; H05K 3/46

(52) U.S. Cl. CPC H05K 1/117; H05K 1/0298; H05K 1/111; H05K 3/002; H05K 3/403; H05K 3/4641; H05K 2201/09181

(57) ABSTRACT

The present application discloses a laminated substrate with wettable flanks, having recesses on its pads that are configured to accommodate the flow of reflow solder. These recesses penetrate the second patterned conductive structure and metal bar of the stacked substrate, extending to the first patterned conductive structure. This structure offers advantages such as controllable morphology and high reliability.

### CROSS-REFERENCE TO RELATED APPLICATIONS

This application claims the benefit of CN application No. 202411721864. 2 filed on Nov. 28, 2024 and incorporated herein by reference.

### TECHNICAL FIELD

Embodiments of the present invention relate to substrates that may be used for semiconductor device packaging, and more particularly but not exclusively, relate to laminated substrates and a method for manufacturing the same.

### BACKGROUND OF THE INVENTION

Laminated substrates are widely used in flip-chip packaging processes. Passive components, power chips, and logic chips could be mounted via flip-chip technology onto these laminated substrates. Additionally, these laminated substrates can be utilized to form embedded die package.

Laminated substrates typically exhibit a certain degree of warpage. Although existing techniques mitigate warpage by incorporating auxiliary structures or replacing dielectric materials, these approaches remain unsuitable for applications demanding stringent packaging reliability. Additionally, forming wettable flanks located at the edges of the laminated substrates is necessary to facilitate solder wetting. How to fabricate wettable flanks with controllable morphology on the edges of laminated substrates remains an unsolved challenge.

### SUMMARY OF THE INVENTION

Embodiments of the present invention are directed to a laminated substrate with wettable flanks. The laminated substrate includes a first dielectric layer having a first surface and a second surface, as well as a second dielectric layer having a first surface and a second surface. The second dielectric layer is formed on the first surface of the first dielectric layer. A first patten conductive structure is formed on the first surface of the first dielectric layer. A metal bar is embedded in the second dielectric layer with its upper surface exposes from the first surface of the second dielectric layer, its lower surface contacts the first patterned conductive structure, and its side surface exposes from the side surface of the laminated substrate. The laminated substrate further includes a second patten conductive structure formed on the first surface of the second dielectric layer. The second patten conductive structure fully covers and directly contacts the upper surface of the metal bar which is exposed from the first surface of the second dielectric layer. The laminated substrate further includes a cavity located at the edge of the laminated substrate. The cavity penetrates the second patten conductive structure and the metal bar, and at least extending to the first patten conductive structure.

Embodiments of the present invention are directed to a laminated substrate with arrays of package units. Spaces between rows and columns of these package unit are Y- and X-direction scribe channels. The laminated substrate includes a first dielectric layer having a first surface and a second surface, as well as a second dielectric layer having a first surface and a second surface. The second dielectric layer is formed on the first surface of the first dielectric layer. A first patten conductive structure is formed on the first surface of the first dielectric layer. Metal bars are embedded in the second dielectric layer with their upper surfaces expose from the first surface of the second dielectric layer. The metal bars have strip like shapes and extend substantially perpendicular to the Y-direction scribe channel or the X-direction scribe channel. The laminated substrate further includes a second patten conductive structure formed on the first surface of the second dielectric layer. The second patten conductive structure fully covers and directly contacts the upper surfaces of the metal bars which are exposed from the first surface of the second dielectric layer.

Embodiments of the present invention are directed to a method for manufacturing a laminated substrate. The method includes a step of providing a laminated substrate with arrays of package units. The spaces between rows and columns of these package unit are Y- and X-direction scribe channels. The laminated substrate includes a first dielectric layer with a first pattern conductive structure formed on of its surface, as well as a second dielectric layer. The method also includes a step of forming metal bars of strip like shapes within the second dielectric layer. Their upper surfaces expose from the second dielectric layer and their lower surfaces contact the first pattern conductive structure. The method includes a step of forming a second pattern conductive structure on a upper surface of the second dielectric layer. The second pattern conductive structure fully covers and directly contacts the upper surface of the metal bars which expose from the second dielectric layer. The method includes a step of forming a photoresist layer on the upper surface of the second dielectric layer. The photoresist layer partially covers the second patterned conductive structure. The method includes a step of etching the laminated substrate to form cavities. The cavities penetrate through the second patterned conductive structure and the metal bars, and contact the first patterned conductive structure. The method includes a step of removing the photoresist layer and forming a solder resist layer on the upper surface of the second dielectric layer and depositing a solder wettable material on the cavities. The method further includes a step of conducting singulation step to get individual package unit.

### BRIEF DESCRIPTION OF DRAWINGS

For a better understanding of the present disclosure, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is an exploded view illustrating a substrate 100 in accordance with an example embodiment of the present disclosure.

FIG. 2(a) is a top view illustrating a first dielectric layer 10A of the substrate 100 in accordance with an example embodiment of the present disclosure.

FIG. 2(b) is a top view illustrating the first dielectric layer 10A of the substrate 100 in accordance with another example embodiment of the present disclosure.

FIG. 2(c) is a top view illustrating the first dielectric layer 10A of the substrate 100 in accordance with another example embodiment of the present disclosure.

FIG. 3 is an exploded view illustrating a substrate 200 in accordance with an example embodiment of the present disclosure.

FIG. 4 is a top view illustrating the first dielectric layer 20A of the substrate 200 in accordance with an example embodiment of the present disclosure.

FIG. 5 shows a schematic diagram of a plurality of first through holes 501 and a fifth through hole 505.

FIG. 6 is a top view illustrating a laminated substrate 601 with wettable flanks in accordance with an embodiment of this disclosure.

FIG. 7 is a cross-section view illustrating how the laminated substrate 601 with wettable flanks in accordance with an embodiment of this disclosure is formed.

FIG. 8 illustrates the laminated substrate 601 according to an embodiment of the present application in step (a) of FIG. 7.

FIG. 9(a) illustrates the laminated substrate 601 according to an embodiment of the present application in step (b) of FIG. 7.

FIG. 9(b) illustrates the laminated substrate 601 according to an embodiment of the present application in step (b) of FIG. 7.

FIG. 10(a) illustrates the laminated substrate 601 according to an embodiment of the present application in step (c) of FIG. 7.

FIG. 10(b) illustrates the laminated substrate 601 according to an embodiment of the present application in step (d) of FIG. 7.

FIG. 11 shows the cross-section view of the laminated substrate 601 after singulation process of the step (g) of FIG. 7.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples.

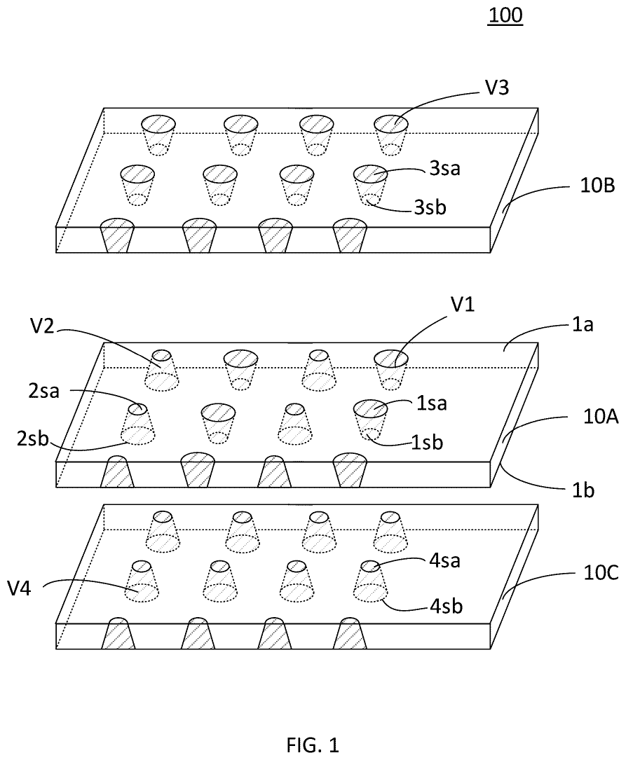

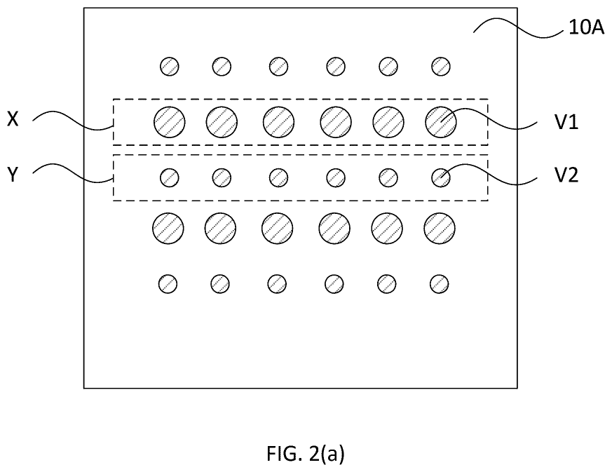

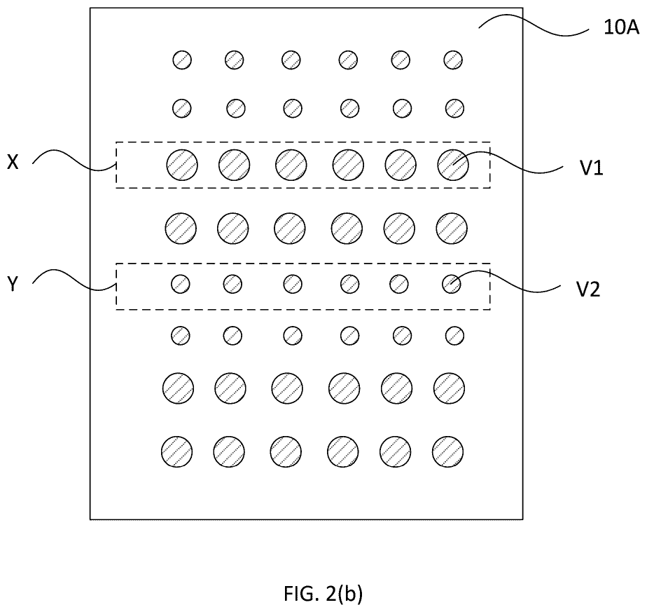

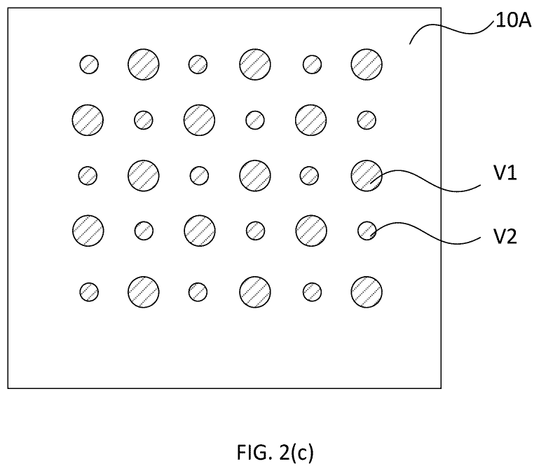

FIG. 1 is an exploded view illustrating a substrate 100 in accordance with an example embodiment. FIG. 2(a) is a top view illustrating a first dielectric layer 10A of the substrate 100 in accordance with an example embodiment.

Referring to FIG. 1, the substrate 100 may include a laminated substrate having three dielectric layers as an example. A first dielectric layer 10A having a first surface 1a and a second surface 1b. A second dielectric layer 10B may be arranged on the first surface 1a and a third dielectric layer 10C may be arranged on the second surface 1b. The substrate 100 may further include patterned conductive structures, such as redistribution layers disposed between the dielectric layers, which are omitted in FIG. 1.

The substrate may further include two kinds of conductive vias with different orientations embedded in the first dielectric layer 10A: a plurality of first conductive vias V1 and a plurality of second conductive vias V2. These conductive vias penetrate the first dielectric layer 10A and expose from the first surface 1a and the second surface 1b. Each of the plurality of first conductive vias V1 includes a surface 1sa exposed on the first surface 1a and a surface 1sb exposed on the second surface 1b. A size of the surface 1sa is larger than that of the surface 1sb. Each of the plurality of second conductive vias V2 includes a surface 2sa exposed on the first surface 1a and a surface 2sb exposed on the second surface 1b. A size of the surface 2sa is smaller than that of the surface 2sb.

In some embodiments, when the first conductive vias V1 and the second conductive vias V2 are cut along several planes parallel to the first surface 1a, a size of cross sections of V1 may increase towards the first surface 1a while a size of the cross sections of V2 may increase towards the second surface 1b.

In some embodiments, when the first conductive vias V1 and the second conductive vias V2 are cut along several planes parallel to the first surface 1a, the size of cross sections of V1 may continually increase towards the first surface 1a while the size of the cross sections of V2 may continually increase towards the second surface 1b.

In some embodiments, when the first conductive vias V1 and the second conductive vias V2 are cut along several planes perpendicular to the first surface 1a, a cross section of each first conductive via V1 includes a gradually increasing width in a direction away from the second surface 1b, and a cross section of each second conductive via V2 includes a gradually increasing width in a direction away from the first surface 1a.

In some embodiments, when the first conductive vias V1 and the second conductive vias V2 are cut along several planes perpendicular to the first surface 1a, the cross section of each first conductive via V1 includes a continually increasing width in the direction away from the second surface 1b, and the cross section of each second conductive via V2 includes a continually increasing width in the direction away from the first surface 1a.

As illustrated in FIG. 1, the plurality of first conductive vias V1 are arranged in rows, which are parallel to the rows composed of the plurality of second conductive vias V2.

The substrate may further include a plurality of third conductive vias V3 embedded in the second dielectric layer 10B. The plurality of third conductive vias V3 penetrate the second dielectric layer 10B and expose from its surfaces. Each of the plurality of third conductive vias V3 includes a surface 3sa away from the first surface 1a and a surface 3sb close to the first surface 1a. The size of surface 3sa is larger than size of surface 3sb. The plurality of third conductive vias V3 are arranged correspondingly with the first conductive vias V1 or the second conductive vias V2 to provide an electrical path.

In some embodiments, when the plurality of third conductive vias V3 are cut along several planes parallel to the first surface 1a, a size of cross sections of each of the plurality of third conductive vias V3 may gradually decrease or continually decrease towards the first surface 1a.

In some embodiments, when the one of the plurality of third conductive vias V3 are cut along several planes perpendicular to the first surface 1a, a cross section of the third conductive via V3 includes a gradually increasing or a continually increasing width in the direction away from the first surface 1a.

The substrate may further include a plurality of fourth conductive vias V4 embedded in the third dielectric layer 10C. The plurality of fourth conductive vias V4 penetrate the third dielectric layer 10C and expose from its surfaces. Each of the plurality of fourth conductive vias V4 includes a surface 4sa close to the second surface 1b and a surface 4sb away from the second surface 1b. A size of surface 4sa is smaller than a size of surface 4sb. The plurality of fourth conductive vias V4 are arranged correspondingly with the first conductive vias V1 or the second conductive vias V2 to provide an electrical path.

In some embodiments, when the plurality of fourth conductive vias V4 are cut along several planes parallel to the first surface 1a, a size of cross sections of each of the plurality of fourth conductive vias V4 may gradually decrease or continually decrease towards the second surface 1b.

In some embodiments, when the plurality of fourth conductive vias V4 are cut along several planes perpendicular to the first surface 1a, a cross section of each fourth conductive vias V4 includes a gradually increasing or a continually increasing width in the direction away from the second surface 1b.

Referring to FIG. 2(a), the plurality of first conductive vias V1 are arranged in rows named X, the plurality of second conductive vias V2 are arranged in rows named Y, and the rows X and the rows Y are arranged in parallel. In some embodiments, the rows X and the rows Y are alternately arranged to form an XYXY layout as shown in FIG. 2(a), while they may have alternative layouts in other embodiments. Referring to FIG. 2(b), every two rows X and every two rows Y are alternately arranged to form an XXYYXXYY layout. Referring to FIG. 2(c), the plurality of first conductive vias V1 and the plurality of second conductive vias V2 are arranged in a matrix, and the most closely adjacent positions of each first conductive vias V1 in the matrix is occupied by one second conductive via V2.

The warpage problem of a laminated substrate is strongly correlated with the degree of warpage of the first dielectric layer 10A. As shown in FIG. 2(a)-FIG. 2(c), the plurality of first conductive vias V1 and the plurality of second conductive vias V2 are arranged alternately in certain pattens to make the stress distribution of the first dielectric layer 10A relatively balanced, which can effectively reduce the degree of warpage of the first dielectric layer 10A. In some embodiments, the plurality of first conductive vias V1 and the plurality of second conductive vias V2 account for 50% respectively. In some other embodiments, the ratios between the plurality of conductive vias V1 and the plurality of second conductive vias V2 can be set accordingly as long as the purpose of reducing warpage can be achieved.

Since the two kinds of conductive vias V1 and V2 are non-uniform conductors in opposite orientations, by arranging them in the described manner can make the resistive distribution of the first dielectric layer more uniform. In addition, by arranging the two kinds of conductive vias V1 and V2 as described, these embodiments can provide a more compact layout compared with conventional solution, which allow more vias to be embedded in the dielectric layer. Therefore, the substrate disclosed in the present disclosure exhibits improved electrical conductivity as well. In some embodiments, those skilled in the art may dispose more layers to form the substrate 100. For example, dispose a fourth dielectric layer on the second dielectric layer 10B and dispose a fifth dielectric layer on the third dielectric layer 10C. In some embodiments, a plurality of conductive vias with one single orientation may be arranged in the fourth and fifth dielectric layers, just as the way the plurality of third conductive vias V3 disposing in the second dielectric layer 10B and the way the plurality of fourth conducive vias V4 disposing in the third dielectric layer 10C described above. Since the warpage of the first dielectric layer 10A is effectively reduced, the laminated substrate with multilayer dielectric layers formed by the additive process shows good flatness. Those skilled in the art may also form and use a substrate with only one dielectric layer, i.e., the first dielectric layer 10A according to this disclosure.

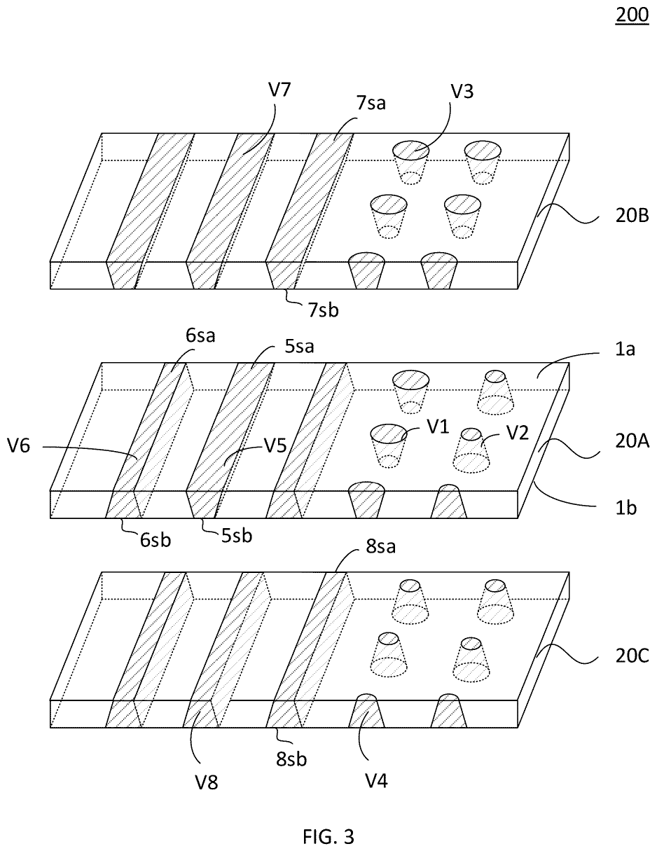

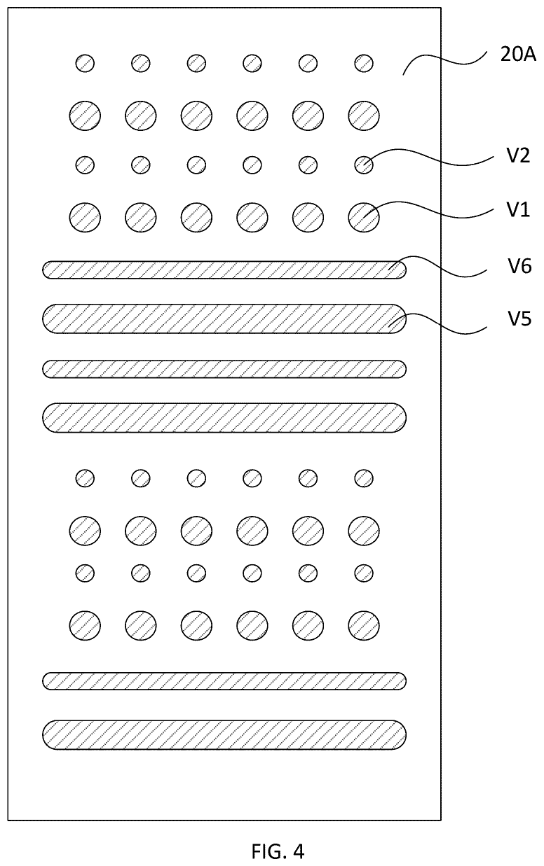

FIG. 3 is an exploded view illustrating a substrate 200 in accordance with an example embodiment. FIG. 4 is a top view illustrating a first dielectric layer 20A of the substrate 200 in accordance with an example embodiment.

Referring to FIG. 3, the substrate 200 is a laminated substrate having three dielectric layers. A first dielectric layer 20A having a first surface 1a and a second surface 1b. A second dielectric layer 20B may be arranged on the first surface 1a and a third dielectric layer 20C may be arranged on the second surface 1b. The substrate 200 may also include patterned conductive structures, such as redistribution layers, disposed between the dielectric layers, which are omitted in FIG. 3.

Same elements in FIG. 1 are provided with same or like reference numerals in FIG. 3 and they may not be addressed here for simplicity. Compared with FIG. 1, the substrate 200 shown in FIG. 3 further include a plurality of fifth conductive vias V5 and a plurality of sixth conductive vias V6.

The plurality of fifth conductive vias V5 has the same orientation as the plurality of first conductive vias V1. More specifically, the plurality of fifth conductive vias V5 penetrate the first dielectric layer 20A and expose from the first surface 1a and the second surface 1b. Each of the plurality of fifth conductive vias V5 includes a surface 5sa exposed on the first surface 1a and a surface 5sb exposed on the second surface 1b. A size of the surface 5sa is larger than that of surface 5sb.

In some embodiments, when the plurality of fifth conductive vias V5 are cut along several planes parallel to the first surface 1a, a size of cross sections of V5 may gradually increase or continually increase towards the first surface 1a.

Each fifth conductive via V5 has a stronger capability of conducting current than each first conductive via V1. In some embodiments, the size of the surface 5sa is larger than the size of the surface 1sa, and the size of the surface 5sb is larger than the size of the surface 1sb. In some embodiments, when these vias are cut along a plane parallel to the first surface 1a, the size of the cross section of each fifth conductive via V5 is larger than that of the each first conductive via V1. In some other embodiments, when these vias are cut along any plane parallel to the first surface 1a, the size of the cross section of each fifth conductive via V5 is larger than that of the each first conductive via V1.

The plurality of six conductive vias V6 has the same orientation as the plurality of second conductive vias V2. More specifically, the plurality of sixth conductive vias V6 penetrate the first dielectric layer 20A and expose from the first surface 1a and the second surface 1b. Each of the plurality of sixth conductive vias V6 includes a surface 6sa exposed on the first surface 1a and a surface 6sb exposed on the second surface 1b. A size of the surface 6sa is smaller than that of the surface 6sb.

In some embodiments, when the plurality sixth conductive vias V6 are cut along several planes parallel to the first surface 1a, a size of cross sections of V6 may gradually increase or continually increase towards the second surface 1b.

Each sixth conductive via V6 has a stronger capability of conducting current than each second conductive via V2. In some embodiments, the size of the surface 6sa is larger than that of the surface 2sa, and the size of the surface 6sb is larger than the size of the surface 2sb. In some embodiments, when these vias are cut along a plane parallel to the first surface 1a, the size of the cross section of each sixth conductive via V6 is larger than that of the each second conductive via V2. In some other embodiments, when the vias are cut along any plane parallel to the first surface 1a, the size of the cross section of each sixth conductive via V6 is larger than that of the each second conductive via V2.

Referring to FIG. 3, only a portion of exposed surfaces of conductive vias V5 and V6 are shown, thus the exposed surfaces of each fifth conductive via V5 and sixth conductive via V6 may have rectangular like shape in FIG. 3. In some embodiments, the exposed surfaces of the fifth and the sixth conductive vias may have strip like shape as shown in FIG. 4, can be considered as elongated rectangle with rounded corners. Referring to FIG. 4, in some embodiments, the strip like conductive vias V5 and V6 extend in a direction parallel to the rows of conductive vias V1 and V2 and the strip like conductive vias V5 and V6 are arranged alternately. Although the conductive vias V1 and V2 shown in FIG. 4 are arranged as the layout shown in FIG. 2(a), they may also be arranged as the layout shown in FIG. 2(b) or FIG. 2(c) in other embodiments.

The substrate may further include a plurality of seventh conductive vias V7 embedded in the second dielectric layer 10B. The plurality of seventh conductive vias V7 penetrate the second dielectric layer 10B and expose from its surfaces. Each of the plurality of seventh conductive vias V7 includes a surface 7sa away from the first surface 1a and a surface 7sb close to the first surface 1a. A size of surface 7sa is larger than a size of surface 7sb. The plurality of seventh conductive vias V7 are arranged correspondingly with the fifth conductive vias V5 or the sixth conductive vias V6 to provide an electrical path.

In some embodiments, when the plurality of seventh conductive vias V7 are cut along several planes parallel to the first surface 1a, a size of cross sections of V7 may gradually decrease or continually decrease towards the first surface 1a.

In some embodiments, when the plurality of seventh conductive vias V7 are cut along several planes perpendicular to the first surface 1a, a cross section of each seventh conductive vias V7 includes a gradually increasing or a continually increasing width in the direction away from the first surface 1a.

Each seventh conductive via V7 has a stronger capability of conducting current than each third conductive via V3. In some embodiments, the size of the surface 7sa is larger than that of the surface 3sa, and the size of the surface 7sb is larger than the size of the surface 3sb. In some embodiments, when these vias are cut along a plane parallel to the first surface 1a, the size of the cross section of each seventh conductive via V7 is larger than that of the each third conductive via V3. In some other embodiments, when the vias are cut along any plane parallel to the first surface 1a, the size of the cross section of each seventh conductive via V7 is larger than that of the each third conductive via V3.

The substrate may further include a plurality of eighth conductive vias V8 embedded in the third dielectric layer 10C. The plurality of eighth conductive vias V8 penetrate the third dielectric layer 10C and expose from its surfaces. Each of the plurality of eighth conductive vias V8 includes a surface 8sa close to the second surface 1b and a surface 8sb away from the second surface 1b. A size of surface 8sa is smaller than a size of surface 8sb. The plurality of eighth conductive vias V8 are arranged correspondingly with the fifth conductive vias V5 or the sixth conductive vias V6 to provide an electrical path.

In some embodiments, when the eighth conductive vias V8 are cut along several planes parallel to the first surface 1a, a size of cross sections of V8 may gradually decrease or continually decrease towards the second surface 1b.

In some embodiments, when the eighth conductive vias V8 are cut along several planes perpendicular to the first surface 1a, a cross section of each eighth conductive vias V8 includes a gradually increasing or a continually increasing width in the direction away from the second surface 1b.

Each eighth conductive via V8 has a stronger capability of conducting current than each fourth conductive via V4. In some embodiments, the size of the surface 8sa is larger than that of the surface 4sa, and the size of the surface 8sb is larger than the size of the surface 4sb. In some embodiments, when these vias are cut along a plane parallel to the first surface 1a, the size of the cross section of each eighth conductive via V8 is larger than that of the each fourth conductive via V4. In some other embodiments, when the vias are cut along any plane parallel to the first surface 1a, the size of the cross section of each eighth conductive via V8 is larger than that of each fourth conductive via V4.

Referring to FIG. 3, there are at least two kinds of electric paths. One kind of electric path may include the third conductive vias V3, the first conductive vias V1/the second conductive V2 and the fourth conductive V4, another kind of electric path may include the seventh conductive vias V7, the fifth conductive vias V5/the sixth conductive vias V6 and the eighth conductive vias V8. The latter of the two has a stronger capability of conducting current and a better thermal performance.

Embodiments of the present invention are also directed to a method for manufacturing the substrate. For example, a dielectric layer, such as partially cured resin or Ajinomoto Build-up Film (ABF), may be provided as the first dielectric layer 10A. A plurality of first through holes may be opened from the first surface 1a, then the first dielectric layer 10A may be flipped to keep its second surface 1b upwards and a plurality of second through holes may be opened from the second surface 1b. The plurality of first through holes and the plurality of second through holes may be filled with or coated with conductive materials to get the first plurality of conductive vias V1 and the second plurality of conductive vias V2. Filling or coating process may be accomplished by electroplating or other process, the conductive material may be copper, nickel, gold, palladium, silver or alloys.

Redistribution layers may be formed on the first surface 1a and the second surface 1b, which is not described here. Then the second dielectric layer 10B may be disposed on the first surface 1a, and at the same time, the third dielectric layer 10C may be disposed on the second surface 1B. A plurality of third through holes penetrating the second dielectric layer 10B may be formed, and at the same time, a plurality of fourth through holes penetrating the third dielectric layer 10C are formed. These through holes may be filled with or coated with conductive materials to form the third conductive vias V3 and the fourth conductive vias V4.

In some embodiments, to manufacture the substrate described with the reference of FIG. 3, a plurality of fifth through holes are formed in the procedure which the plurality of first through holes are formed, while a plurality of sixth through holes are formed in the procedure which the plurality of second through holes are formed. These through holes may be filled with or coated with conductive materials to form the fifth conductive vias V5 and the sixth conductive vias V6.

In some embodiments, to manufacture the substrate described with the reference of FIG. 3, a plurality of seventh through holes are formed in the procedure which the plurality of third through holes are formed, while a plurality of eighth through holes are formed in the procedure which the plurality of fourth through holes are formed. These through holes may be filled with or coated with conductive materials to become the plurality of seventh conductive vias V7 and the plurality of eighth conductive vias V8.

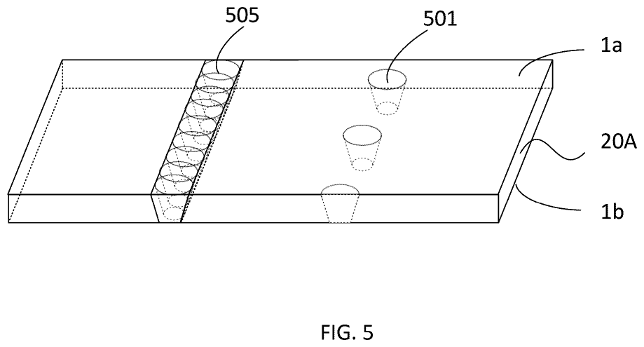

As described before and shown in FIG. 4, the exposed surfaces of the fifth and the sixth conductive vias may have strip like shape, can be considered as elongated rectangle with rounded corners. In one embodiment, the fifth and sixth through holes for forming the plurality of fifth conductive vias V5 and the plurality of six conductive vias V6 can be manufactured by continuously laser drilling on the first dielectric layer 20A. FIG. 5 shows a schematic diagram of forming the plurality of first through holes 501 and the fifth through hole 505 simultaneously in the same process step. As shown in FIG. 5, multiple openings formed by laser drilling overlap each other and form a strip like shape hole region, i.e., the fifth through hole 505. After being filled with metal in subsequent steps, the fifth through hole 505 forms the fifth conductive via V5. The shape of the fifth through hole 505 can be adjusted by adjusting the laser drilling tool, laser energy, and the degree of overlap between the multiple overlapping openings.

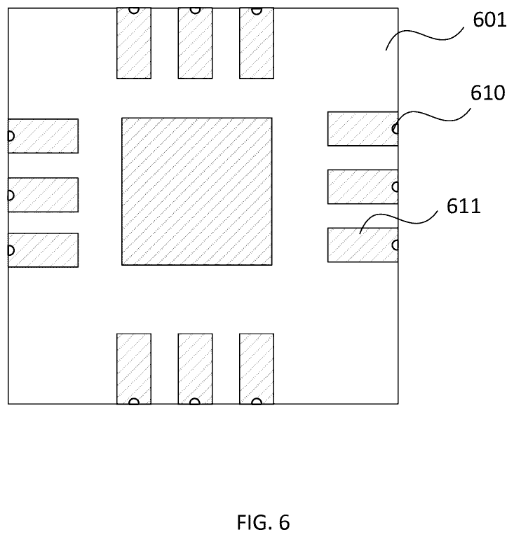

FIG. 6 is a top view illustrating a laminated substrate 601 with wettable flanks in accordance with another example embodiment of this disclosure. The laminated substrate 601 includes pads 611 with recesses 610 which are configured to accommodate the flow of reflow solder. Semiconductor devices can be embedded within the laminated substrate 601 by conventional methods which will not be described in this disclosure. The laminated substrate 601 with wettable flank discussed in this disclosure can actually refer to an embedded die package including the laminated substrate 601 and semiconductor devices. That is, those skilled in the art should know that the term “laminated substrate” through this disclosure not only means a laminated substrate but also can refer to a laminated substrate with embedded semiconductor devices.

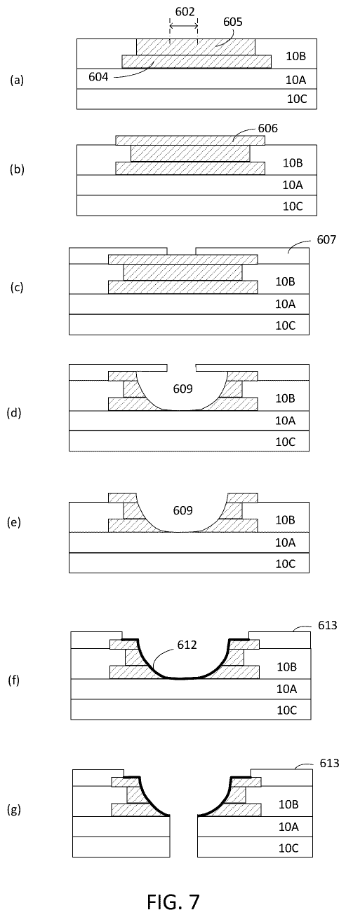

This application also provides a method for forming the laminated substrate 601 with wettable flanks. FIG. 7 shows a cross-sectional view of the laminated substrate 601 with a scribe channel (for example, a Y-direction scribe channel 602). Steps (a) through (f), as shown in FIG. 7, are schematic diagrams of the laminated substrate 601 before the scribe channel region is cut. Step (g), also shown in FIG. 7, is a schematic diagram of the laminated substrate 601 after the scribe channel region is cut. The method includes the following steps:

Referring to step (a) of FIG. 7, a laminated substrate having the first dielectric layer 10A, the second dielectric layer 10B, and the third dielectric layer 10C is provided. A first patterned conductive structure 604 is formed on the first dielectric layer 10A and is embedded in the second dielectric layer 10B. A metal bar 605 is also embedded in the second dielectric layer 10B. The upper surface of the metal bar 605 exposes from the surface of the second dielectric layer 10B. The shape of the metal dam 605 will be described in detail later.

Referring to step(b) of FIG. 7, the manufacturing method further includes forming a second patterned conductive structure 606 on the upper surface of the second dielectric layer 10B. The second patterned conductive structure 606 may be processed into the pad 611 on the outer surface of the laminated substrate 601 in a subsequent step. The second patterned conductive structure 606 covers the exposed surface of the metal bar 605 and is in direct contact with the exposed surface of the metal bar 605. The second patterned conductive structure 606 may be a copper foil or other conductive metal layer with a necessary thickness.

Referring to step (c) of FIG. 7, the manufacturing method further includes forming a photoresist layer 607 on the upper surface of the second dielectric layer 10B, partially covering the second patterned conductive structure 606. Referring to step (d) of FIG. 7, the laminated substrate is etched, so a portion of the second patterned conductive structure 606 that is not covered by the photoresist layer 607 is in direct contact with etching liquid. As the etching liquid erodes and diffuses, another portion of the second patterned conductive structure 606 that is originally covered by the photoresist layer 607 and the metal bar 605 that is originally fully covered by second patterned conductive structure 606 are also etched. The parameters of the etching process can be adjusted to control the depth and width of the cavity 609 formed by the etching process. For example, in one embodiment, the cavity 609 obtained in the etching process penetrates through the second patterned conductive structure 606, the metal bar 605, and stops at the first patterned conductive structure 604. In another embodiment, the cavity 609 obtained in the etching process penetrates through the second patterned conductive structure 606, the metal bar 605, and the first patterned conductive structure 604.

Referring to step (e) of FIG. 7, the photoresist layer 607 is removed in this step. Referring to step (f) of FIG. 7, a solder resist layer 613 is formed on the upper surface of the second dielectric layer 10B, partially covering the second patterned conductive structure 606. A portion of the second patterned conductive structure 606 and the cavity 609 are not covered by the solder resist layer 613. A solder wettable material 612 is deposited on the area not covered by the solder resist layer 613. In one embodiment, NiAu is selectively deposited on the area not covered by the solder resist layer 613 by an electroless plating process. In other embodiments, other metals may be deposited.

Referring to step (g) of FIG. 7, during the singulation step, the laminated substrate is cut along the scribe channel, and the laminated substrate located within the scribe channel is completely removed. A portion of the structure of the cavity 609 is also removed, and the remaining portion becomes part of the edge of the laminated substrate 601. After this singulation step is completed, the second patterned conductive structure 606 is fabricated as the pad 611, and the cavity 609 is fabricated as the recess 610.

It should be noted that, although in the embodiment provided in FIG. 7, there're only three stacked dielectric layers, the laminated substrate 601 with wettable flank in accordance with this disclosure may include more dielectric layers. For example, the laminated substrate 601 may include five dielectric layers. For laminated substrates with more than three dielectric layers, the second dielectric layer 10B, the first dielectric layer 10A, and the third dielectric layer 10C shown in FIG. 7 correspond, respectively, to the outermost dielectric layer, the second outermost dielectric layer, and the dielectric layer below the second outermost dielectric layer. Some critical steps in the above process will be described in detail below.

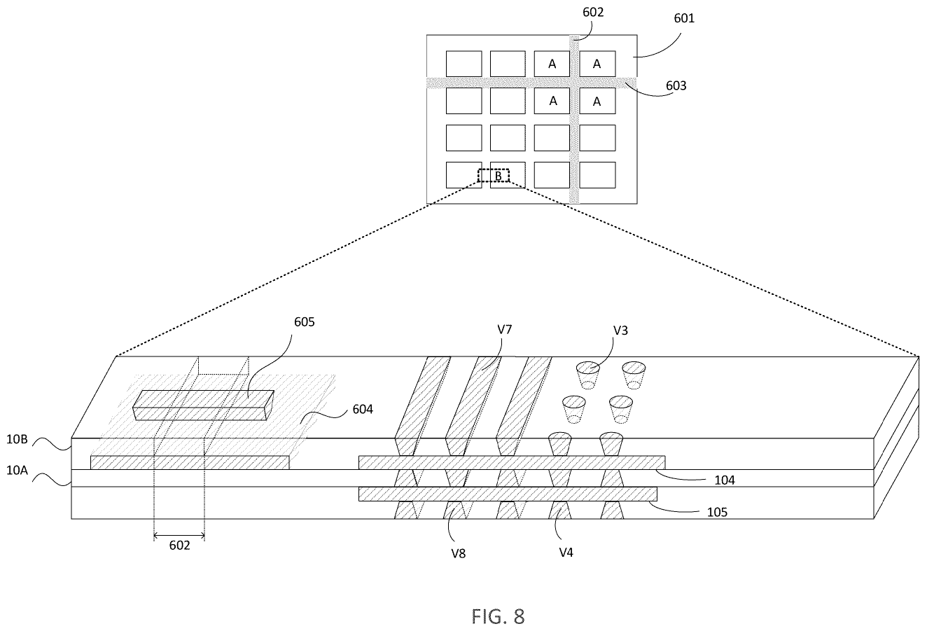

FIG. 8 illustrates the laminated substrate 601 in step (a) of FIG. 7, according to an embodiment of the present application. The laminated substrate 601 is fabricated in sheet form with arrays of package units A. These units will be divided into individual units through a singulation step after subsequent steps are completed. The spaces between the rows and columns of package unit A are Y- and X-direction scribe channels, shown as gray areas in FIG. 8. During the singulation process of step (g), cutting can be performed along the Y-and X-direction scribe channels, respectively.

FIG. 8 also shows an enlarged, perspective view of a portion of the Y-direction scribe channel 602. In this embodiment, the first patterned conductive structure 604 is stacked on the first dielectric layer 10A. The first patterned conductive structure 604 may be copper foil or another conductive metal of the required thickness. The metal bar 605 is formed in the second dielectric layer 10B and contacts the first patterned conductive structure 604 directly. The strip like metal bar 605 extends substantially perpendicular to the Y-direction scribe channel 602. In one embodiment, the length of the metal bar exceeds the width of the Y-direction scribe channel 602. In one example, the surface of the metal bar 605 exposed from the upper surface of the second dielectric layer 10B has a larger size than the surface of the metal bar 605 expose from the lower surface of the second dielectric layer 10B. In one embodiment, the metal bar 605 may be fabricated simultaneously using the same process as the fifth through hole conductor V5 shown in FIG. 5. Specifically, as illustrated in FIG. 5, multiple openings formed by laser drilling overlap each other and form a strip like shape hole region. After being filled with metal in other subsequent steps, the strip like shape hole is fabricated as the metal bar 605.

FIG. 8 shows an enlarged perspective view of region B (the dashed-line box) on the laminated substrate 601. This view includes a portion of the Y-direction scribe channel 602 and a portion of an adjacent package unit A. The view illustrates an exemplary structure of the package unit A, including the laminated substrate structure of FIG. 3 and, at the same time, illustrates the scribe channel region (for example, the Y-direction scribe channel 602) for fabricating the wettable flank. In one embodiment, the first patterned conductive structure 604 is formed in the same step as a further patterned conductive structure 104 of package unit A is formed. And similarly, the metal bar 605 is formed in the same step as the seventh conductive via V7 is formed in the second dielectric layer 10B.

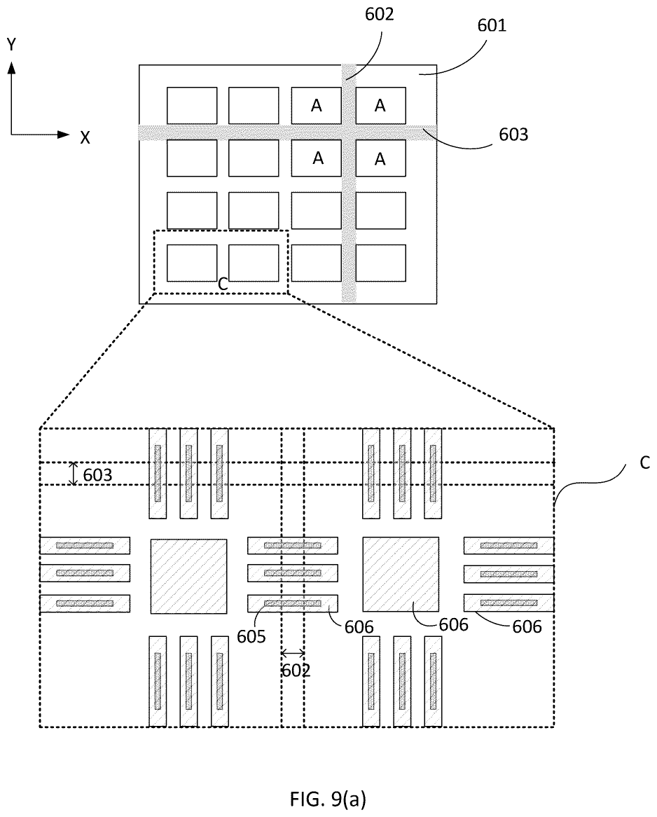

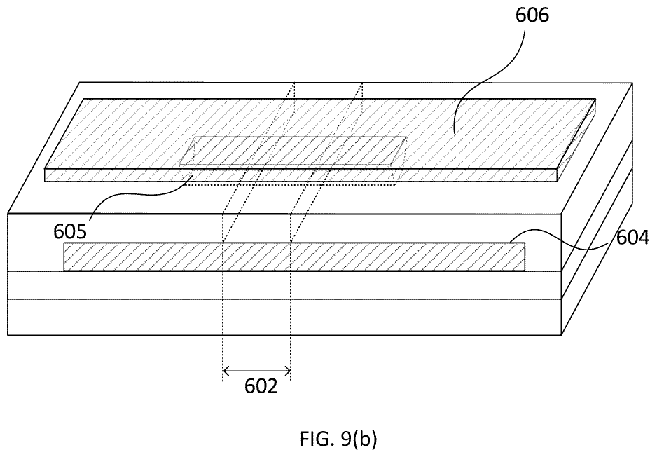

FIG. 9(a) and FIG. 9(b) illustrate the laminated substrate 601 in step (b) of FIG. 7, according to an embodiment of the present application. In this step (b), the second patterned conductive structure 606 is formed on the upper surface of the second dielectric layer 10B. The second patterned conductive structure 606 can be further processed and serve as the terminal of the package unit A, for example, subsequent steps involve applying gold plating to the second patterned conductive structure 606 to form the pads 611. FIG. 9(a) shows a region C (the dashed-line box) on the laminated substrate 601. The region C includes two adjacent package units A, along with portions of Y-direction scribe channel 602 and X-direction scribe channel 603 located around them. Multiple second patterned conductive structures 606 are arranged at the Y-direction scribe channel 602, extending substantially perpendicular to direction of the Y-direction scribe channel 602. Similarly, multiple second patterned conductive structures 606 are provided at the X-direction scribe channel 603, extending substantially perpendicular to direction of the X-direction scribe channel 603. The length of each second patterned conductive structure 606 extends beyond the width of the scribe channel and into the region of adjacent package unit A. FIG. 9(b) shows a cross-section of a region of the laminated substrate at the Y-direction scribe channel where the wettable flank will be formed. As shown in FIG. 9(b), the second patterned conductive structure 606 fully covers the exposed surface of the metal bar 605 which exposes from the second dielectric layer 10B. In one embodiment, the Y-direction scribe channel 602 has width of approximately 250 micrometers, a second patterned conductive structure 606 may be a rectangle having a length of approximately 1050 micrometers and a width of approximately 250 micrometers, a metal bar may have a length of approximately 650 micrometers.

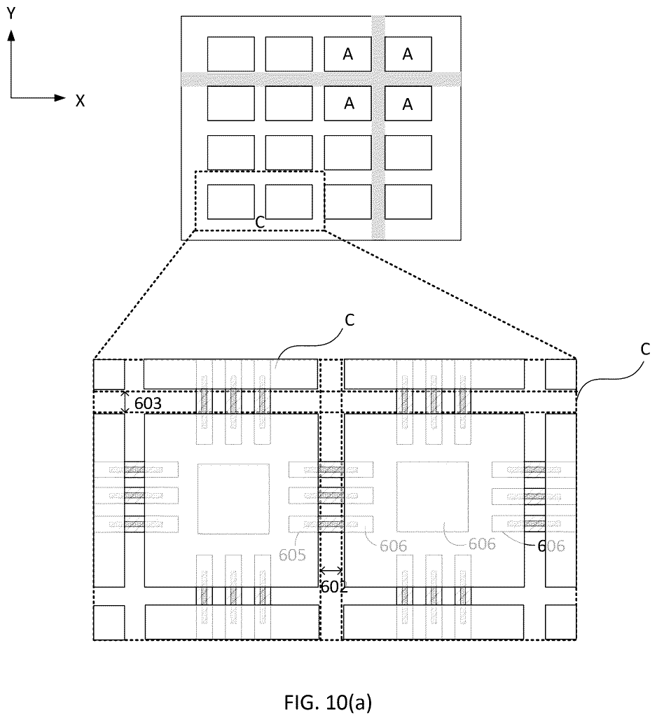

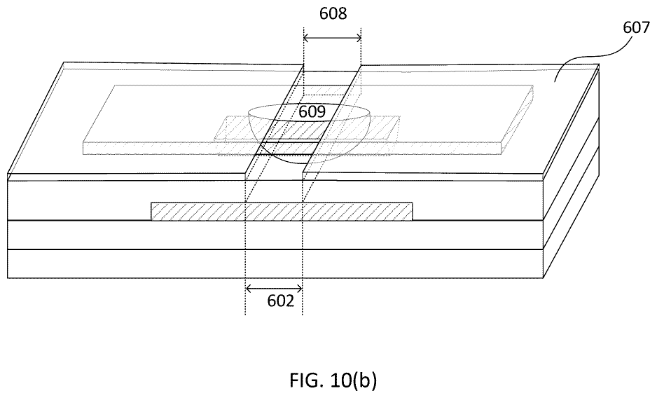

FIG. 10(a) illustrates the laminated substrate 601 in step (c) of FIG. 7, and FIG. 10(b) illustrates the laminated substrate 601 in step (d) of FIG. 7, according to an embodiment of the present application. FIG. 10(a) also shows the region C (the dashed-line box) on the laminated substrate 601. The region C includes two adjacent package units A, along with portions of Y-direction scribe channel 602 and X-direction scribe channel 603 located around them. In step (c), the photoresist layer 607 is formed on the surface of the laminated substrate while does not cover the entire surface. The enlarged view of region C in FIG. 10(a) shows that the photoresist layer 607 includes multiple rectangular patterns arranged in an array. The rectangular patterns are spaced apart by a certain distance to precisely expose the Y-direction scribe channels 602 and X-direction scribe channels 603. In other embodiments, however, the spacing between the patterns may be wider, exposing a broader surface area of the laminated substrate than the scribe channels. FIG. 10(b) shows a cross-section of a region of the laminated substrate at the Y-direction scribe channel 602 where the wettable flank will be formed. It illustrates that, the adjacent rectangular patterns of photoresist layer 607 are spaced apart by a distance 608, which fully exposes the Y-direction scribe channel 602. FIG. 10(b) also shows the cavity 609 formed by the etching process during the step (d).

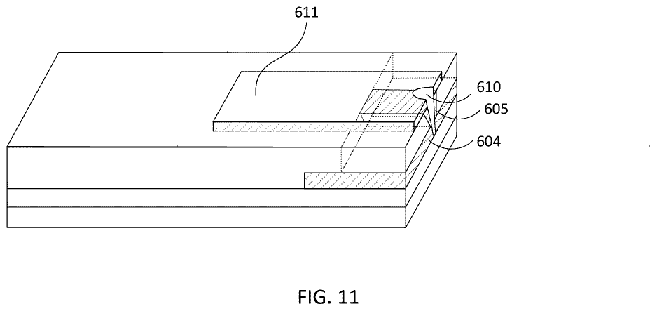

FIG. 11 shows the cross-section view of the laminated substrate after singulation process of the step (g) of FIG. 7. Note that for clarity of illustration, the solder wettable material 612 is omitted in FIG. 11, showing only the structure beneath the solder wettable material 612. As shown, after singulation process, a portion of the laminated substrate 601 located at the Y-direction scribe channels 602 is removed. In this step(g), the second patterned conductive structure 606 previously arranged on the upper surface of the second dielectric layer 10B has been fabricated into the pad 611 (solder wettable material 612 not shown) located at the edge of the package unit A, and the previously etched cavity 609 has been fabricated into the recess 610 capable of being filled with solder.

As shown in FIG. 11, the cavity 609 for wettable flank is formed entirely within the metal material. In FIG. 11, for example, the cavity 609 penetrates the second patterned conductive structure 606, the metal bar 605, and the first patterned conductive structure 604. In other embodiments, the cavity 609 may penetrate the second patterned conductive structure 606 and the metal bar 605, and at least extending to the first patterned conductive structure 604. In other embodiment, the cavity 609 may penetrate the second patterned conductive structure 606 and the metal bar 605, extending into and stopping within the first patterned conductive structure 604 The etching process in step (d), only metal materials are being etched, enabling precise control and excellent process repeatability. Compared to other methods of forming wettable flanks in laminated substrate, this approach avoids etching dielectric materials. This allows for the fabrication of wettable flanks of controllable quality.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A laminated substrate with wettable flanks, comprising:
a first dielectric layer having a first surface and a second surface;
a second dielectric layer having a first surface and a second surface, wherein the second dielectric layer is formed on the first surface of the first dielectric layer;
a first patten conductive structure formed on the first surface of the first dielectric layer;
a metal bar embedded in the second dielectric layer, wherein its upper surface exposes from the first surface of the second dielectric layer, its lower surface contacts the first patterned conductive structure, and its side surface exposes from the side surface of the laminated substrate;
a second patten conductive structure formed on the first surface of the second dielectric layer, wherein the second patten conductive structure fully covers and directly contacts the upper surface of the metal bar which is exposed from the first surface of the second dielectric layer;
a cavity located at the edge of the laminated substrate, wherein the cavity penetrates the second patten conductive structure and the metal bar, and at least extending to the first patten conductive structure.

2. The laminated substrate of claim 1, wherein the cavity exposes from both the first surface of the second dielectric layer and the side of the laminated substrate.

3. The laminated substrate of claim 1, wherein the laminated substrate further includes a conductive via penetrating the second dielectric layer, a surface of the conductive via exposed from the second dielectric layer and the surface of the conductive via has a strip like shape.

4. The laminated substrate of claim 3, wherein the conductive via and the metal bar are fabricated simultaneously by a same process.

5. The laminated substrate of claim 1, wherein the cavity penetrates the second pattern conductive structure, the metal bar and the first pattern conductive structure.

6. The laminated substrate of claim 1, wherein the cavity is covered by a layer of a solder wettable material.

7. A laminated substrate with arrays of package units, wherein spaces between rows and columns of these package unit are Y-and X-direction scribe channels, the laminated substrate includes:
a first dielectric layer having a first surface and a second surface;
a second dielectric layer having a first surface and a second surface, wherein the second dielectric layer is formed on the first surface of the first dielectric layer;
a plurality of first patten conductive structures formed on the first surface of the first dielectric layer;
a plurality of metal bars embedded in the second dielectric layer with their upper surfaces expose from the first surface of the second dielectric layer, each of the plurality of metal bars has strip like shape and extends substantially perpendicular to the Y-direction scribe channel or the X-direction scribe channel;
a plurality of second patten conductive structures formed on the first surface of the second dielectric layer, wherein each of the plurality of second patten conductive structures fully covers and directly contacts the upper surface of each of the plurality of metal bars which is exposed from the first surface of the second dielectric layer.

8. The laminated substrate with arrays of package units of claim 7, each of the plurality of metal bars extends beyond the width of the scribe channel and reaches into two adjacent package units.

9. The laminated substrate with arrays of package units of claim 7, each of the plurality of first patten conductive structures extends beyond the width of the scribe channel and reaches into two adjacent package units.

10. The laminated substrate with arrays of package units of claim 7, each of the plurality of second patten conductive structures extends beyond the width of the scribe channel and reaches into two adjacent package units.

11. The laminated substrate with arrays of package units of claim 7, wherein the laminated substrate further includes a conductive via penetrating the second dielectric layer, a surface of the conductive via exposed from the second dielectric layer and the surface of the conductive via has a strip like shape.

12. The laminated substrate with arrays of package units of claim 11, wherein the conductive via and the metal bar are fabricated simultaneously by a same process.

13. A method for manufacturing a laminated substrate, comprising:
providing a laminated substrate with arrays of package units, wherein spaces between rows and columns of these package unit are Y-and X-direction scribe channels, and wherein the laminated substrate includes a first dielectric layer with a plurality of first pattern conductive structures formed on its surface, as well as a second dielectric layer;
forming a plurality of metal bars of strip like shapes within the second dielectric layer, wherein their upper surfaces expose from the second dielectric layer and their lower surfaces contact the first pattern conductive structure;
forming a plurality of second pattern conductive structures on a upper surface of the second dielectric layer, wherein each of the plurality of second pattern conductive structure fully covers and directly contacts the upper surface of each of the plurality of metal bars which exposes from the second dielectric layer;
forming a photoresist layer on the upper surface of the second dielectric layer, wherein the photoresist layer partially covers the second patterned conductive structure;
etching the laminated substrate to form cavities, wherein the cavities penetrate through the second patterned conductive structure and the metal bars, and contact the first patterned conductive structure;
removing the photoresist layer and forming a solder resist layer on the upper surface of the second dielectric layer and depositing a solder wettable material on the cavities;
conducting singulation step to get individual package unit.

14. The method of claim 7, as for forming metal bars of strip like shapes within the second dielectric layer, the method further comprises:
forming the plurality of metal bars at the Y-direction scribe channels and X-direction scribe channels, wherein each of the plurality of metal bars extends substantially perpendicular to the Y-direction scribe channel or the X-direction scribe channel, and wherein the length of each of the plurality of metal bars exceeds the width of the Y-direction scribe channel or the X-direction scribe channel.

15. The method of claim 14, each of the plurality of metal bars extends and reaches into two adjacent package units.

16. The method of claim 7, the method further comprises forming conductive vias in the package units which penetrate the second dielectric layer, wherein their surface which expose from the upper surface of the second dielectric layer have strip like shapes.

17. The method of claim 9, wherein the conductive vias and the plurality of metal bars are fabricated simultaneously by a same process.

18. The method of claim 9, as for forming conductive vias in the package units, the method further comprises:
forming a strip like hole region by forming multiple openings which overlap each other;
filling the strip like hole region with metal.

19. The method of claim 9, as for forming a photoresist layer on the upper surface of the second dielectric layer, the method further comprises:
forming the photoresist layer having multiple rectangular patterns arranged in an array, wherein the rectangular patterns are spaced apart by a certain distance to expose the Y-direction scribe channels and X-direction scribe channels.

20. The method of claim 9, as for etching the laminated substrate to form cavities, each cavity formed in this method penetrates through each of the plurality of second patterned conductive structures, each of the plurality of metal bars and each of the plurality of first patterned conductive structures.
